(19) United States
(12) Patent Application Publication
(10) Pub. No.: US 2015/0054581 A1
(43) Pub. Date: Feb. 26, 2015

(54) COMBINATION NMOS/PMOS POWER AMPLIFIER

(71) Applicant: QUALCOMM Incorporated, San Diego, CA (US)

(72) Inventor: Kasra Omid-Zohoor, San Francisco, CA (US)

(73) Assignee: QUALCOMM Incorporated, San Diego, CA (US)

(21) Appl. No.: 14/010,191

(22) Filed: Aug. 26, 2013

(51) Int. Cl. H03F 3/193; H03F 3/24; H03F 3/21

(52) U.S. Cl. CPC H03F 3/193; H03F 3/211; H03F 3/245
USPC 330/277

(57) ABSTRACT

A combination NMOS/PMOS power amplifier is disclosed. In an exemplary embodiment, the amplifier includes a first amplifier section comprising a first NMOS transistor that is configured to provide a first amplified output and a second amplifier section comprising a first PMOS transistor that is configured to provide a second amplified output. The first PMOS transistor is coupled to the first NMOS transistor at a selected node to reduce capacitance variation at the selected node.

### BACKGROUND

1. Field

The present application relates generally to the operation and design of power amplifiers, and more particularly, to the operation and design of CMOS power amplifiers.

2. Background

In typical CMOS power amplifier (PA) designs, there is a tradeoff between power efficiency and linearity. To achieve sufficient power efficiency and linearity, a CMOS PA is operated in Class AB mode. In Class AB mode, the PA input transistor gate is biased at a DC operating point slightly above the transistor threshold voltage. Around this operating point, there is a large change in the transistor's gate-source capacitance with voltage. This variable gate-source capacitance has been shown to be a dominant source of PA nonlinearity. In an effort to reduce this nonlinearity, a dummy PMOS device is placed alongside the input NMOS device to reduce the variance in input capacitance. The disadvantage of this technique is that the dummy PMOS device increases the overall PA input capacitance, which reduces gain and power efficiency.

Therefore, it is desirable to have a CMOS power amplifier that overcomes the above described problems to provide improved power efficiency and linearity.

### BRIEF DESCRIPTION OF THE DRAWINGS

The foregoing aspects described herein will become more readily apparent by reference to the following description when taken in conjunction with the accompanying drawings wherein:

FIG. 1 shows a detailed exemplary embodiment of a transmitter front end for use in a wireless device;

FIG. 2 shows a detailed exemplary embodiment of a NMOS/PMOS power amplifier;

FIG. 3 shows a detailed exemplary embodiment of a NMOS/PMOS power amplifier; and

FIG. 4 shows an exemplary embodiment of a NMOS/PMOS amplifier apparatus configured for improved efficiency and linearity.

### DETAILED DESCRIPTION

The detailed description set forth below in connection with the appended drawings is intended as a description of exemplary embodiments of the invention and is not intended to represent the only embodiments in which the invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well known structures and devices are shown in block diagram form in order to avoid obscuring the novelty of the exemplary embodiments presented herein.

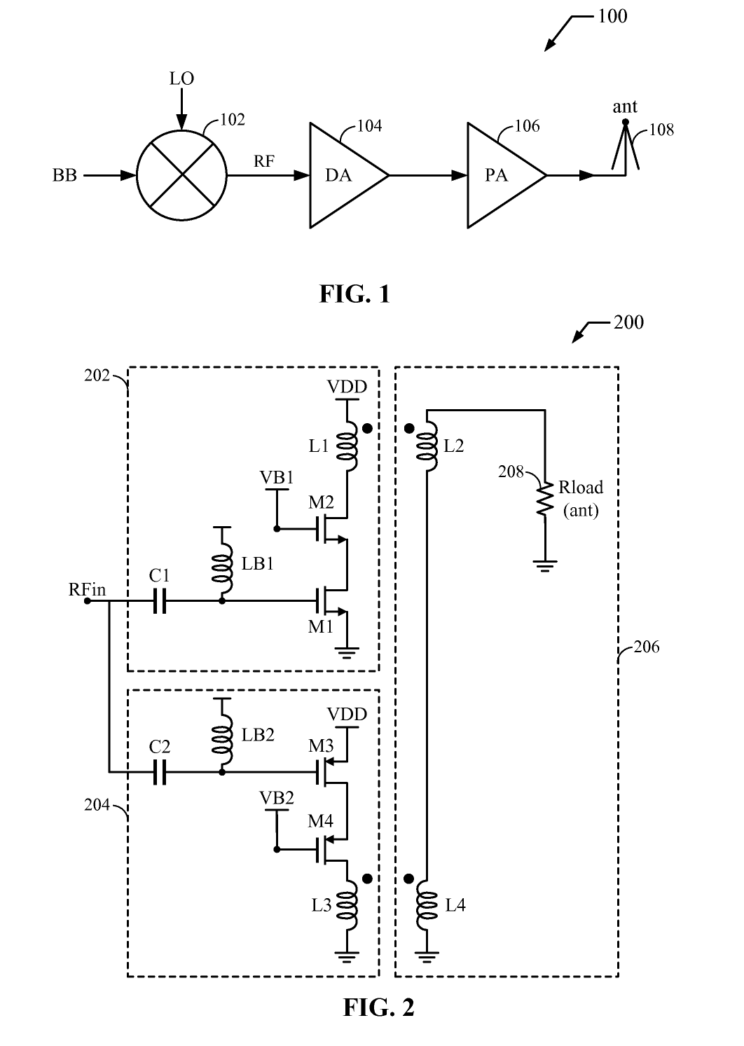

FIG. 1 shows a detailed exemplary embodiment of a transmitter front end 100 for use in a wireless device. The front end comprises a mixer or up-converter 102 that receives a baseband (BB) signal and up-converts this baseband signal to an RF signal based on a local oscillator (LO) signal. The RF signal is input to driver amplifier (DA) 104 that outputs an amplified RF signal that is input to an exemplary embodiment of a CMOS power amplifier (PA) 106. The PA 106 provides additional amplification to the RF signal, which is then provided to an antenna 108 for transmission.

In various exemplary embodiments, the PA 106 comprises parallel NMOS/PMOS amplifier sections coupled to a combining transformer. The power outputs of the two amplifier sections are combined on a secondary transformer coil of the combining transformer and provided to a resistive load (i.e., antenna 108). The advantages of this parallel NMOS/PMOS architecture are superior linearity due to capacitive-compensation and better gain and power efficiency from power combining

FIG. 2 shows a detailed exemplary embodiment of a NMOS/PMOS power amplifier 200. For example, the NMOS/PMOS PA 200 is suitable for use as PA 106 shown in FIG. 1.

In an exemplary embodiment, the NMOS/PMOS PA 200 comprises a first amplifier section 202 comprising NMOS transistors M1 and M2 connected in parallel with a second amplifier section 204 comprising PMOS transistors M3 and M4. The PA 200 also comprises a secondary transformer section 206.

An RF input signal (RF_{IN}) is input to both the first 202 and second 204 amplifier sections. Two input coupling capacitors C1 and C2 operate to receive the RF input signal and isolate the DC gate bias of the first 202 and second 204 amplifier sections. Inductors LB1 and LB2 are large choke inductors used to apply separate gate biases. In an exemplary embodiment, the transistors M1 and M3 are input transistors and the transistors M2 and M4 are thick oxide cascode transistors for robustness under large-signal operation. The outputs of the first and second amplifier sections are provided at inductors L1 and L3, respectively. The two parallel NMOS and PMOS amplifier sections are configured to reduce input capacitance variation, which reduces amplitude modulation (AM) distortion and/or phase modulation (PM) distortion and thereby increases PA linearity. For example, the transistors M1 and M3 have capacitances (Cgs) that vary with changing voltage in opposite ways (i.e., one gets larger the other gets smaller) so that when these capacitances combine, reduced capacitance variation results.

In an exemplary embodiment, the secondary transformer 206 comprises inductors L2 and L4, which are inductively coupled to inductors L1 and L3, respectively. The secondary transformer 206 provides power combining so that the output powers of the two amplifier sections 202 and 204 provided at inductors L1 and L2 are combined onto the secondary transformer 206 inductors L2 and L4. This increases the overall output power of the PAs and increases energy efficiency. The combined output power is provided to a load 208, which in an exemplary embodiment is the antenna 108 shown in FIG. 1.

Therefore, in various exemplary embodiments, a parallel NMOS/PMOS PA with parallel combining transformer is disclosed. The parallel NMOS/PMOS architecture provides superior linearity due to reduced input capacitance variation from the NMOS/PMOS combination and better gain and power efficiency resulting from power combining.

A typical amplifier maintains a constant gain for low-level input signals. However, at higher input levels, the amplifier goes into saturation and its gain decreases. The 1 dB compression point (P1 dB) indicates the power level that causes the gain to drop by 1 dB from its small signal value. In various exemplary embodiments, the NMOS/PMOS amplifier increases the P1 dB compression point to provide greater linearity than conventional amplifiers.

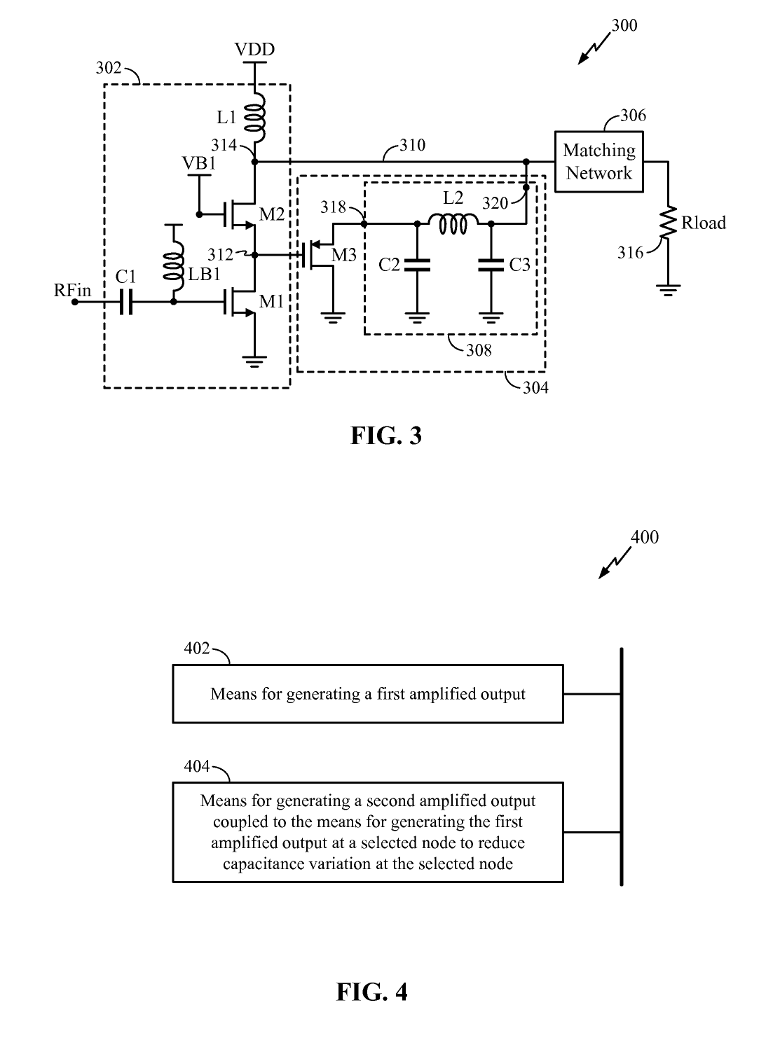

FIG. 3 shows a detailed exemplary embodiment of a NMOS/PMOS amplifier 300 that comprises main 302 and auxiliary 304 amplifier sections. The main amplifier section 302 comprises NMOS transistors M1 and M2 connected in a cascode configuration to receive an RF input signal (RF_{IN}) and generate an amplified RF signal on signal line 310. For example, the transistor M1 comprises a source terminal connected to signal ground, a gate terminal coupled to receive the RF input signal (RF_{IN}) through capacitor C1, and a drain terminal connected to a source terminal of the transistor M2 at node 312. The inductor LB1 further biases the transistor M1. The transistor M2 also comprises a gate terminal connected to receive a bias signal (V_{B1}) and a drain terminal connected to an inductor L1 at output terminal 314. The inductor L1 is further connected to a supply voltage (V_{DD}). A matching network 306 is connected to match the amplified RF signal on the signal line 310 to an output load 316.

The auxiliary amplifier section 304 comprises a PMOS transistor M3 having a gate terminal connected to the source terminal of the transistor M2. The transistor M3 also has a drain terminal connected to signal ground and a source terminal connected to a first terminal 318 of a Pi matching circuit 308. The PMOS transistor M3 is configured to provide reduced capacitance variation at the node 312 and to provide a signal at the terminal 318.

In an exemplary embodiment, the output of the input common source transistor (M1) is fed into the gate of the PMOS common drain (CD) auxiliary amplifier (M3). This provides the reduction of the capacitance variation at the node 312. For example, the transistors M2 and M3 have gate-to-source capacitances (Cgs) that vary with changing voltage in opposite ways (i.e., one gets larger the other gets smaller) so that when these capacitances combine, reduced capacitance variation results. This reduced capacitance variation at node 312 reduces AM distortion and/or PM distortion and thereby increases PA linearity.

The Pi circuit 308 comprises a second terminal 320 connected to the output terminal 314 via the signal line 310. Between the first 318 and second 320 terminals are capacitors C2, C3 and inductor L2 connected in a Pi configuration. The Pi circuit 308 operates to provide isolation between the output terminal 314 of the first amplifier 302 and the terminal 318 of the auxiliary amplifier 304.

In various exemplary embodiments, the Pi matching circuit 308 (C2, L2, and C3) transforms impedance in both directions. As a result, the PMOS CD auxiliary amplifier (M3) sees high impedance instead of the transformed R_{LOAD} from looking into matching network. The cascode PA (M2) sees high impedance instead of 1/gm3 from looking into the source of M3. In this configuration, neither the main 302 nor auxiliary 304 amplifiers load one another.

FIG. 4 shows an exemplary embodiment of an NMOS/PMOS amplifier apparatus 400 configured for improved linearity. For example, the apparatus 400 is suitable for use as the NMOS/PMOS amplifier 200 shown in FIG. 2, or as the NMOS/PMOS amplifier 300 shown in FIG. 3. In an aspect, the apparatus 400 is implemented by one or more modules configured to provide the functions as described herein. For example, in an aspect, each module comprises hardware and/or hardware executing software.

The apparatus 400 comprises a first module comprising means (402) for generating a first amplified output, which in an aspect comprises the main amplifier stage 202 shown in FIG. 2 or the main amplifier stage 302 shown in FIG. 3.

The apparatus 400 comprises a second module comprising means (404) for generating a second amplified output coupled to the means (402) for generating the first amplified output at a selected node to reduce capacitance variation at the selected node, which in an aspect comprises auxiliary amplifier stage 204 shown in FIG. 2 or the auxiliary amplifier stage 304 shown in FIG. 3.

Those of skill in the art would understand that information and signals may be represented or processed using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof It is further noted that transistor types and technologies may be substituted, rearranged or otherwise modified to achieve the same results. For example, circuits shown utilizing PMOS transistors may be modified to use NMOS transistors and vice versa. Thus, the amplifiers disclosed herein may be realized using a variety of transistor types and technologies and are not limited to those transistor types and technologies illustrated in the Drawings. For example, transistors types such as BJT, GaAs, MOSFET or any other transistor technology may be used.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal In the alternative, the processor and the storage medium may reside as discrete components in a user terminal.

In one or more exemplary embodiments, the functions described may be implemented in hardware, software, firmware, or any combination thereof If implemented in software, the functions may be stored on or transmitted over as one or more instructions or code on a computer-readable medium. Computer-readable media includes both non-transitory computer storage media and communication media including any medium that facilitates transfer of a computer program from one place to another. A non-transitory storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The description of the disclosed exemplary embodiments is provided to enable any person skilled in the art to make or use the invention. Various modifications to these exemplary embodiments will be readily apparent to those skilled in the art, and the generic principles defined herein may be applied to other embodiments without departing from the spirit or scope of the invention. Thus, the invention is not intended to be limited to the exemplary embodiments shown herein but is to be accorded the widest scope consistent with the principles and novel features disclosed herein.

What is claimed is:

1. An apparatus comprising:
a first amplifier section comprising a first NMOS transistor that is configured to provide a first amplified output; and
a second amplifier section comprising a first PMOS transistor that is configured to provide a second amplified output, the first PMOS transistor coupled to the first NMOS transistor at a selected node to reduce capacitance variation at the selected node.

2. The apparatus of claim 1, the first amplifier section providing the first amplified output at a first inductor and the second amplified section providing the second amplified output at a second inductor.

3. The apparatus of claim 2, further comprising a secondary transformer coil coupled to the first and second inductors to combine signal power from the first and second inductors at the secondary transformer coil.

4. The apparatus of claim 1, the first amplifier section comprising a second NMOS transistor coupled in a cascode configuration with the first NMOS transistor.

5. The apparatus of claim 1, the first amplifier section and the second amplifier section having input terminals that are connected to receive an RF input signal.

6. The apparatus of claim 1, the second amplifier section comprising a second PMOS transistor coupled in a cascode configuration with the first PMOS transistor.

7. The apparatus of claim 1, the first PMOS transistor having a gate terminal connected to a source terminal of the first NMOS transistor.

8. The apparatus of claim 7, the second amplifier section comprising an attenuation circuit connected between a source terminal of the first PMOS transistor and the second amplified output.

9. The apparatus of claim 8, the first amplified output coupled to the second amplified output.

10. An apparatus comprising:
means for generating a first amplified output; and
means for generating a second amplified output coupled to the means for generating the first amplified output at a selected node to reduce capacitance variation at the selected node.

11. The apparatus of claim 10, further comprising means for coupling the first amplified output to a secondary coil and means for coupling the second amplified output to the secondary coil.

12. The apparatus of claim 10, the means for generating the first amplified output comprising a first NMOS transistor, and the means for generating the second amplified output comprising a first PMOS transistor.

13. The apparatus of claim 12, the means for generating the first amplified output comprising a second NMOS transistor coupled in a cascode configuration with the first NMOS transistor.

14. The apparatus of claim 12, the means for generating the second amplified output comprising a second PMOS transistor coupled in a cascode configuration with the first PMOS transistor.

15. The apparatus of claim 12, the means for generating the first amplified output and the means for generating the second amplified output having input terminals that are connected to receive an RF input signal.

16. The apparatus of claim 14, the first PMOS transistor having a gate terminal connected to a source terminal of the first NMOS transistor.

17. The apparatus of claim 14, the means for generating the second amplified output comprising an attenuation circuit connected between a source terminal of the first PMOS transistor and the second amplified output.
